(19) United States
(12) Patent Application Publication
(10) Pub. No.: US 2024/0179847 A1
(43) Pub. Date: May 30, 2024

(54) PALLADIUM PLATING CATALYST LAYER BY LASER INDUCED FORWARD TRANSFER

(71) Applicant: STMICROELECTRONICS S.r.l., Agrate Brianza (IT)

(72) Inventor: Paolo CREMA, VIMERCATE (IT)

(73) Assignee: STMICROELECTRONICS S.r.l., Agrate Brianza (IT)

(21) Appl. No.: 18/060,481

(22) Filed: Nov. 30, 2022

(51) Int. Cl. H05K 3/10; C23F 17/00; C25D 5/54; H05K 3/18

(52) U.S. Cl. CPC H05K 3/107; C23F 17/00; C25D 5/54; H05K 3/181; H01L 21/4857

(57) ABSTRACT

The present disclosure is directed to a method of forming a conductive trace in a substrate. A pattern of the trace is formed in the substrate by a laser machining technique. The pattern of the trace is covered by palladium colloid. The palladium colloid is transferred to the patterned substrate by a laser-induced forward transfer (LIFT) technique. The palladium colloid is converted to a palladium plating catalyst layer by a palladium acceleration process. The palladium plating catalyst layer provides a sufficient catalyst to grow a metal seeding layer by an electroless copper deposition technique. In addition, the palladium plating catalyst layer includes portions of tin material which increases adhesion of the metal seeding layer into the substrate. After growing the metal seeding layer, the pattern of the trace is filled by a copper layer through an electrochemical deposition technique.

### BACKGROUND

### Technical Field

The present disclosure is directed to the fabrication of conductive traces for interconnecting integrated circuits in package devices, and in particular, to a method for forming conductive traces from metal colloids using a laser-induced forward transfer (LIFT) technique.

### Description of the Related Art

Electrically conductive traces are broadly employed for interconnections in electrical circuits such as printed circuit board (PCB) as well as integrated circuits (ICs). The electrically conductive traces comprising copper are widely used due to high electrical conductivity, flexibility, electrostatic discharge, electromagnetic interference (EMI) protection, and radio-frequency interference protection of copper. One way of forming the conductive traces is to form openings in a non-conductive or dielectric substrate such as a polymer substrate and then plate a conductive metal in the openings. In some instances, aluminum, copper, silver, and nickel are plated in the openings. The plating process may be performed by electroplating, which an electric current is used to transfer metal in an aqueous solution to a surface. In order to facilitate the electroplating process, a seed layer may be deposited using an electroless plating technique prior to electroplating. The seed layer provides nucleation sites where the electroplated metal initially forms.

Typically, the electroless plating requires pretreatment of the substrate to create catalytic sites on the substrate surface. In some electroless plating processes, the catalytic sites are created using a molding compound enriched with a catalyst. However, the substrate pretreatment and the catalyst enrichment need extra processing steps and time which increases the cost and reduces the efficiency of the metallization process. In addition, as integrated circuits and related packages continue to shrink, the associated features including conductive traces shrink in size as well. Methods that allow selectively forming catalytic sites to achieve site selective electroplating of metal for conductive trace formation are needed.

### BRIEF SUMMARY

The present disclosure is directed to a method of forming a conductive trace in a substrate. In particular, the method includes forming a metal trace in a substrate to create interconnections between the components of one or more circuits. In some embodiments, the metal trace includes copper material. The substrate may be any conventional plastic materials or nature and synthetic polymers. An opening is formed in the substrate by a laser machining technique. A layer of palladium colloids is transferred to the surfaces of opening by a laser-induced forward transfer (LIFT) technique. Using the LIFT technique benefits applying palladium colloid only onto the surfaces of the opening for use as a catalyst in subsequent electroless copper plating. Hence, the substrate no longer needs to be enriched with any catalysts. Afterwards, the palladium colloid is converted to a palladium plating catalyst layer by a palladium acceleration process. The palladium plating catalyst layer provides a sufficient catalyst to grow a metal seeding layer by an electroless copper deposition technique. In addition, tin (Sn) in the palladium plating catalyst layer helps to increase adhesion of the metal seeding layer onto the substrate. After growing the metal seeding layer, the pattern of the trace is filled by a copper layer through an electrochemical deposition technique.

### BRIEF DESCRIPTION OF THE SEVERAL VIEWS OF THE DRAWINGS

In the drawings, identical reference numbers identify similar features or elements. The size and relative positions of features in the drawings are not necessarily drawn to scale.

FIGS. 1A-1C are cross-sectional views illustrating forming a palladium colloid layer over surfaces of an opening in a substrate, in accordance with some embodiments.

FIG. 2 illustrates forming a donor layer by applying a palladium colloid solution onto a donor substrate, in accordance with some embodiments.

FIG. 3 illustrates transferring the donor layer of FIG. 2 onto surfaces of the opening of FIG. 1C using a laser-induced forward transfer (LIFT) method, in accordance with some embodiments.

FIGS. 4A-4D are cross-sectional views illustrating forming a conductive trace in a substrate, in accordance with some embodiments.

FIGS. 5A-5F are cross-sectional views illustrating forming a conductive trace including vias in a substrate, in accordance with some embodiments.

FIGS. 6A-6C are embodiments of circuits formed from the conductive trace of FIGS. 5A-5F, in accordance with some embodiments.

FIG. 7 is a flowchart schematically illustrating a process of forming a conductive trace described in FIGS. 1A-5F, in accordance with some embodiments.

### DETAILED DESCRIPTION

In the following description, numerous specific details are given to provide a thorough understanding of embodiments. The embodiments can be practiced without one or several specific details, or with other methods, components, materials, etc. In other instances, well-known structures, materials, or operations are not shown or described in detail to avoid obscuring aspects of the embodiments.

Throughout the specification, claims, and drawings, the following terms take the meaning explicitly associated herein, unless the context clearly dictates otherwise. The term “herein” refers to the specification, claims, and drawings associated with the current application. The phrases “in one embodiment,” “in another embodiment,” “in various embodiments,” “in some embodiments,” “in other embodiments,” and other variations thereof refer to one or more features, structures, functions, limitations, or characteristics of the present disclosure, and are not limited to the same or different embodiments unless the context clearly dictates otherwise. As used herein, the term “or” is an inclusive “or” operator, and is equivalent to the phrases “A or B, or both” or “A or B or C, or any combination thereof,” and lists with additional elements are similarly treated. The term “based on” is not exclusive and allows for being based on additional features, functions, aspects, or limitations not described, unless the context clearly dictates otherwise. In addition, throughout the specification, the meaning of “a,” “an,” and “the” include singular and plural references.

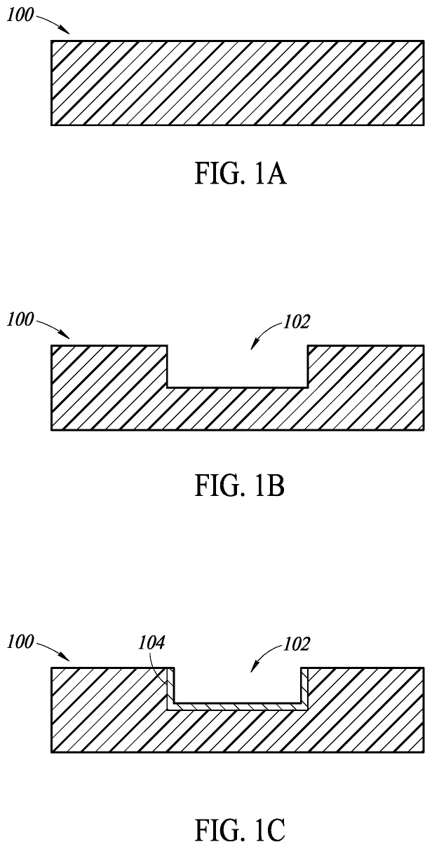

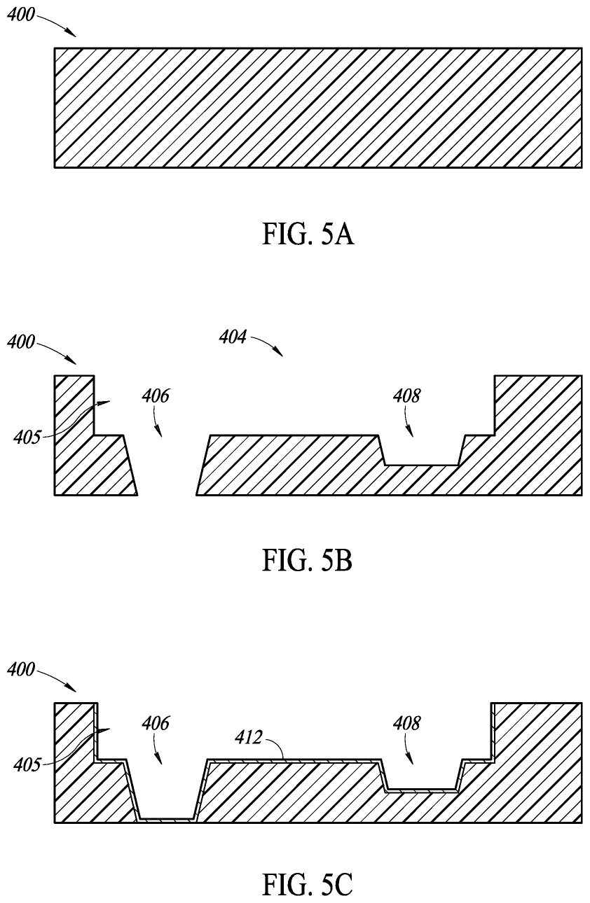

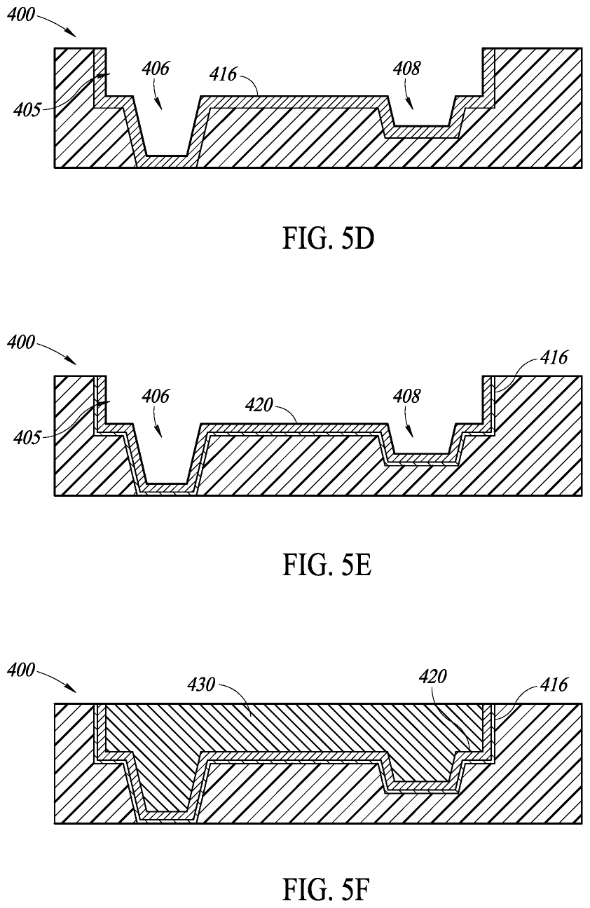

FIGS. 1A-1C illustrate processes of preparing catalytic sites in a substrate 100 for forming conductive traces. The conductive traces may include copper to form interconnection in electrical chips. In addition, the conductive traces may provide interconnections in different electrical circuits such as circuits that are implemented in a printed circuit board (PCB). In various embodiments, the conductive traces may form interconnection of a single sided PCB (one metal layer). However, the same process may be used to form the conductive traces in a double-sided PCB (two metal layers on both sides of one substrate or dielectric layer), or a multi-layer PCB (outer and inner layers of metal, alternating with layers of substrate or dielectric). The PCB and substrates of the present disclosure are components of integrated circuits and integrated circuit packages. More detail about the process for multi-layer circuits is described in FIGS. 5A-5F.

FIG. 1A illustrates a substrate 100 to be metallized for creating the conductive traces. In some embodiments, the substrate 100 is a PCB substrate. Exemplary dielectric materials that can be used in such PCB substrate include FR-2 (phenolic paper or phenolic cotton paper impregnated with phenol formaldehyde resin), FR-4 (woven fiberglass cloth impregnated with epoxy resin), aluminum or an insulated metal substrate clad with thermally conductive thin dielectric, or a flexible material such as polyimide foils or polyimide-fluoropolymer composite foils. Other PCB substrate materials may be used including other variations of impregnated papers and woven fiberglass impregnated with epoxy resin, as well as polyimides. In some other embodiments, the substrate 100 may be formed of a material such as glass. Different types of glass may include fused silica glass, soda-lime glass, borosilicate glass, aluminosilicate glass, aluminoborosilicate glass, or the like, or any combination thereof, which may optionally include one or more alkali and/or alkaline earth modifiers. Alternatively, the substrate 100 may be formed of a material such as a ceramic (e.g., alumina, aluminum nitride, beryllium oxide, or the like or any combination thereof), a glass-ceramic, a glass-bonded ceramic, a polymer (e.g., a polyamide, a polyimide, or the like or any combination thereof), a glass-filled polymer, a glass fiber-reinforced polymer, or the like or any combination thereof. In addition, the substrate 100 may be a molding compound layer, e.g., an Epoxy Molding Compound layer, of an integrated circuit (IC) package. In some embodiments, the substrate 100 is used in manufacturing semiconductor devices using laser direct structuring (LDS) or direct copper interconnection (DCI) technology.

In some embodiments, the substrate 100 may include plastic polymers such as epoxy modified tetrafunctional material, or other insulating or non-conductive materials. The plastic polymer may include a broad range of materials, for instance polycarbonate (PC), polycarbonate/acrylonitrile butadiene styrene (PC/ABS), acrylonitrile butadiene styrene (ABS), or liquid-crystal polymer (LCP). In some embodiments, the substrate 100 is a silicon on insulator (SOI) layer substrate or a silicon on sapphire (SOS) substrate.

FIG. 1B illustrates forming an opening 102 in the substrate 100. The opening 102 determines the position of a conductive trace subsequently formed. The dimension of the opening 102 also determines the depth, length and width of the conductive trace. In some embodiments, the opening 102 is formed by a laser patterning method (e.g., laser-machining process). In this condition, parameters of a beam of the laser controls the dimension of the opening 102. For instance, the laser may be a pulsed laser. In this condition, a pulse duration, pulse energy, and beam spot size of the laser is tuned based on the desired dimension of the opening 102. In some embodiments, the depth of the opening 102 may be about 10-15 μm.

In some alternative examples, different etching techniques such as photolithography and etching process may be used instead of the laser patterning. The etching process may include a dry etch, a wet etch, or a combination of dry etch and wet etch. The dry etching process may implement fluorine-containing gas (e.g., CF₄, SF₆, CH₂F₂, CHF₃, and/or C₄F₈), chlorine-containing gas (e.g., Cl₂, CHCl₃, CCl₄, and/or BCl₃), bromine-containing gas (e.g., HBr and/or CHBr₃), oxygen-containing gas, iodine-containing gas, other suitable gases and/or plasmas, or combinations thereof.

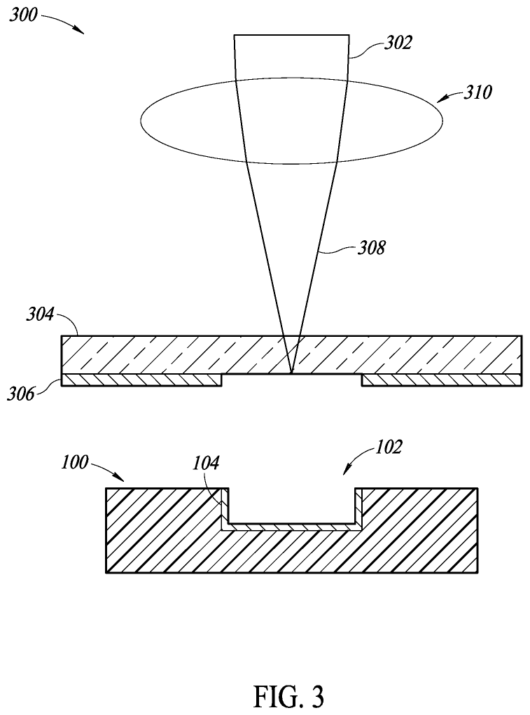

FIG. 1C illustrates forming a metal precursor layer 104 on surfaces of the opening 102, after patterning the substrate 100 and forming the opening 102. In various embodiments, the metal precursor layer 104 is formed conformally. The term “conformally” is used herein for case of description for a layer having substantially the same thickness over various regions, e.g., the bottom and sidewall surfaces of the opening 102. In some embodiments, the metal precursor layer 104 is formed using a laser-induced forward transfer (LIFT) method. During the LIFT method, the metal precursor layer 104 is selectively transferred from a donor substrate into the opening 102. A pattern of the laser exposure on the donor substrate during the LIFT process corresponds to the pattern of the opening 102 formed in the substrate 100. Thus, the metal precursor layer 104 is only transferred to the patterned opening areas including the opening 102. More detail of the LIFT method is described in FIG. 3.

In some embodiments, the metal precursor layer 104 includes a noble metal colloid material. Noble metal colloids are desirable for catalytic applications because they can provide enhanced reactivity, stability, and selectivity for the electroless deposition of the metallic layers on the substrate. In addition, the colloidal structure adds desired properties to the catalyst such as large specific areas, adjustable electronic states and transitions by the colloid size, and capability of doping and fine-tuning by surface-bound ligands or mixed-in secondary components. In some embodiments, the noble metal includes palladium. Alternatively, the metal precursor layer 104 may include different noble metals such as gold and platinum. In addition, the metal precursor layer 104 may include materials such as aluminum, titanium, tungsten, copper, nickel, chromium, germanium, selenium, or the like, oxides thereof, nitrides thereof, an alloy thereof, or any other combination thereof.

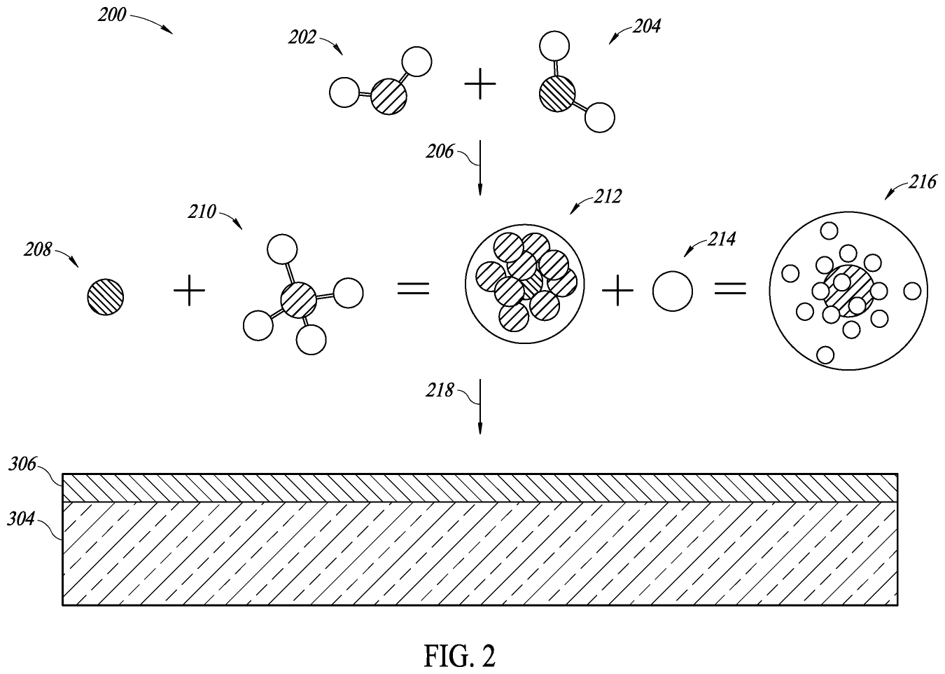

In some embodiments, the noble metal colloid is a palladium colloid which is an effective catalyzer for metallization processes. In some embodiments, the palladium colloid includes palladium-tin (Pd—Sn) colloidal particles. The presence of tin (Sn) in the palladium colloid increases adhesion of the metal precursor layer 104 to the substrate 100. In various embodiments, the metal precursor layer 104 is formed by first forming a donor layer (for example, donor layer 306 in FIG. 2) on a donor substrate, and then transferring the donor layer onto the surfaces of the opening 102 during the LIFT process. In some embodiments, the formation of the donor layer on the donor substrate may include applying a metal colloid solution on the donor substrate using, for example, spin coating, solution-deposition, screen-printing, or blade-deposition. In some embodiments, the donor layer is formed from a palladium colloid solution. The palladium colloid has very high stability and high dissolvability in standard organic solvents that benefit strong catalytic activities.

FIG. 2 illustrates forming a palladium colloid solution and then forming a donor layer 306 on a donor substrate from the palladium colloid solution. In this embodiment, during process 200 tin-chloride (SnCl₂) 202 reacts with palladium-chloride (PdCl₂) 204. The reaction between tin-chloride (SnCl₂) 202 and palladium-chloride (PdCl₂) 204 may include an oxidation-reduction (redox) reaction which generates black palladium nanoparticles. Afterwards, during process 206, the black palladium nanoparticles generate palladium nucleus 208, while excess chlorine (Cl) is attached to SnCl₂ to generate SnCl₄ 210 in the solution. In this condition, the process 206 refers to as a nucleation process. During a cation process, the palladium nucleus 208 adsorbs cations in the solution (e.g., Sn²⁺ or Sn⁺⁴) to form palladium-tin (Pd—Sn) colloidal particles 212. By adsorbing the cations of tin (Sn⁺ⁿ) from the solution, negatively charged chlorine (Cl⁻) 214 remains in the solution. In this condition, the charge of palladium-tin (Pd—Sn) colloidal particles 212 is positive, and thus, adsorbs negatively charged chlorine (Cl⁻) 214 as an anion to form an electrically neutral palladium micelle 216.

Palladium micelle 216 forms the palladium colloid solution to be deposited on a donor substrate 304. During process 218, the palladium colloid solution including palladium micelles 216 is deposited on a surface of the donor substrate 304 to form the donor layer 306. In some embodiments, palladium micelles 216 are formed in a uniform size. In some embodiments, palladium micelles 216 are formed in different sizes. The process 218 may include a spin coating method in some embodiments.

After deposition of the donor layer 306, the donor substrate 304 is ready to be utilized in the LIFT process. In some embodiments, the chlorine shell may be removes from the palladium colloid during a drying out process of the donor layer 306. Consequently, a dried palladium colloid is formed from the palladium colloid solution that creates the donor layer 306. Existence of the tin shell protects the palladium nucleus as well as increase adhesion of the palladium colloid to the substrate 100 when the palladium colloid is transferred into the opening 102 of the substrate 100 in FIG. 1C to create a stable conductive trace. The stability of the palladium colloid may be determined based on stability of the mechanical and chemical properties of the conductive trace over the time. Less changes of the mechanical and chemical properties over the time is a consequence of the higher stability.

FIG. 3 illustrates a LIFT process 300 that can be used to transfer the donor layer 306 to the substrate 100 to form the metal precursor layer 104 described in FIG. 1C. Comparing to the conventional metallization process in which a specific molding compound enriched by a catalyst material is employed to create catalytic sites, by utilizing the LIFT process to selectively deposit the metal colloid only in the opening 102, there is no need for using a specific molding compound. In addition, in the conventional metallization process, after applying the molding compound that is enriched with the catalyst, an illumination, e.g., by an ultra-violate (UV) laser, is required to activate the catalyst in the molding compound for the subsequent metal electroless deposition. Using the specific molding compound and enriching it by the catalyst material as well as the subsequent illumination step increase complexity and cost of the metallization process. The LIFT process of the present disclosure is capable of depositing the noble metal catalyst to the specific sites of the substrate without need for the catalyst-enriched specific molding compound. Therefore, LIFT process of the present disclosure not only reduces complexity and cost of the metallization process but allows for the site-selective catalytic metal deposition. In addition, when the LIFT process is combined with the palladium colloid which offers an enhancement in stability of the metallic layer, a higher quality (e.g., based on the mechanical and chemical parameters) of the conductive trace is achievable concurrent with a reduction in the cost and complexity of the process.

The LIFT process 300 uses a laser 302 to illuminate the donor substrate 304. The donor substrate 304 includes the donor layer 306 that is prepared for the LIFT process during the processes described in FIG. 2. The LIFT process transfers the donor layer 306 into the opening 102 of the substrate 100. The transferred donor layer 306 creates a pattern of the metal precursor layer 104 on the substrate 100, as described in FIG. 1C. In various embodiments, the donor substrate 304 includes a material that is transparent in the frequency range of the laser 302. In some examples, the transparent material of the donor substrate 304 may include some optical features to alter a laser beam 308 passing through the transparent material. For instance, the transparent material may focus the laser beam 308 into the donor layer 306, which results in higher energy concentration on the donor layer 306 and higher resolution of the patterning linewidth.

In some embodiments, the laser 302 is a pulsed laser. Thus, the energy of the laser 302 is adjustable by a pulse repetition rate. In some alternative embodiments, the laser 302 may be a continuous wave (CW) laser or a quasi-continuous wave (QCW) laser. The energy of the laser 302 may be adjusted to different values corresponding to the opening dimensions as well as the material of the donor layer 306. In addition, the laser beam 308 of the laser 302 may be tilted to imping the portions of the donor layer 306 which are covering the sidewalls of the opening 102. In some embodiments, a lens 310 may be positioned between the laser 302 and the donor substrate 304. The lens 310 adjusts the spot size of the laser beam 308. In addition, the lens 310 may tilt a direction of the laser beam 308 to imping the portions of the donor layer 306 to be deposited on the sidewalls of the opening 102. In some embodiments, the substrate 100 may be tilted instead of the laser 302 to position the sidewalls of the opening 102 in a direct exposure of the laser 302. In some embodiments, the laser beam 308 remains perpendicular on a focal plane to transfer the donor layer 306 to the surface of the opening 102, while shadow of the laser beam 308 exposes the donor layer 306 to be transferred into the sidewalls of the opening 102. In various embodiments, energy density of the laser 302 is in a range of 0.1-10 mj/mm² at a wavelength of 480 nm.

In some embodiments, the laser 302 may be used for patterning the substrate 100 to create the opening 102, in addition to performing the LIFT process. In this condition, an operation mode of the laser 302 may be set to a laser-machining mode. The laser-machining mode may utilize a higher energy and different wavelength than a LIFT mode operation. In such embodiment, in a first step, the laser 302 operates in the laser-machining mode to create the opening 102 in the substrate 100 based on a stored layout in a control system of the laser 302. In a next step, the laser 302 switches to the LIFT mode and the donor substrate 304 moves between the laser 302 and the substrate 100, in which the donor layer 306 is faced toward the substrate 100. Then the laser 302 impinges the donor substrate 304 and the donor layer 306 in the areas of the patterned opening 102. The laser 302 may use the same layout as the stored layout for the laser-machining process, because the machined areas that creates the opening 102 need to be covered by the donor layer 306. Alternatively, different layout may be used for each step. In some examples, the patterning of the substrate 100 may be performed by mechanical drilling or photolithography process instead of the laser-machining.

In various embodiments, a thickness of the donor layer 306 may be about 10 nanometers (nm) to 300 micrometers (μm). In some embodiments, a thickness of the donor layer 306 may be about 100 nanometers (nm) to 100 micrometers (μm). The thickness of the donor layer 306 may be designed based on the dimensions of the opening 102 as well as the thickness needed for the subsequent metal plating. In some embodiments, the thickness of the donor layer 306 is about 100 nm.

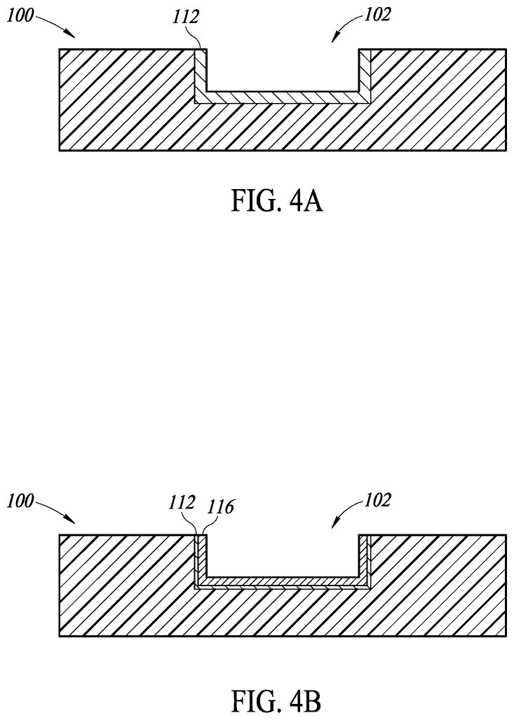

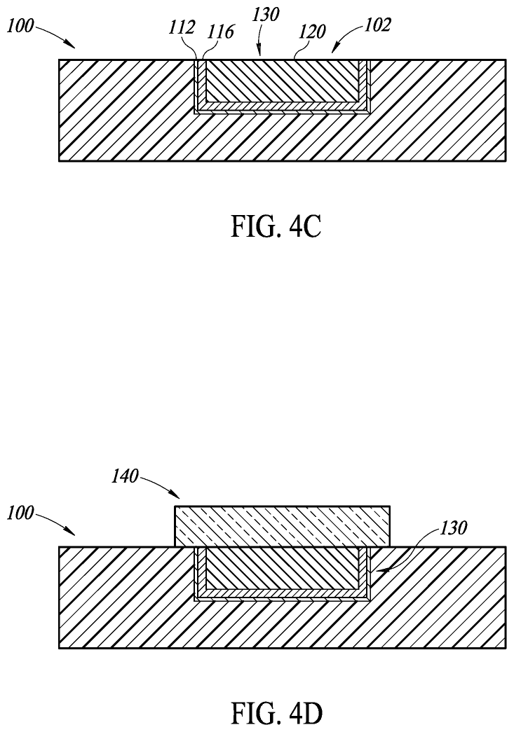

FIG. 4A illustrates forming a plating catalyst layer 112 from the metal colloid of the metal precursor layer 104 in FIG. 1C, after performing the LIFT process. The process described in FIG. 4A includes acceleration of the metal colloid. The acceleration may include a thermal process or a mechanical process. During the acceleration process the viscosity and interaction force in the metal colloid is changed by increasing the temperature of the metal colloid or coupling a mechanical vibration to the surface covered by the metal colloid. As a result of the acceleration, the surface covered by the metal colloid is drained to form a solid film on the substrate 100. In some embodiments, an acid may be used to accelerate the metal colloid. In some embodiments, when the metal precursor layer 104 includes a palladium colloid, the process of FIG. 4A includes acceleration of the palladium colloid. During the acceleration process of the palladium colloid, the tin shell is removed from the palladium nucleus. In this condition, an active catalyst layer of palladium remains in the opening 102 to form the plating catalyst layer 112. Although the tin shell is removed from the palladium colloid during the acceleration process, still portions of tin material remain in the plating catalyst layer 112. The remaining tin material provides better adhesion of the metallic layer into the opening 102 during the metallization process. In some embodiments, the metal precursor layer 104 in FIG. 1C may have a thickness about 100 micrometers (μm), while the plating catalyst layer 112 has a thickness about 5 angstroms (Å) after the acceleration process. In some embodiments, removing the tin shell may be based on dissolving of the tin shell into an accelerator solution. The accelerator solution may include a hydrochloride acid or different aqueous chloride, organic acid, mixed acid, and polar organic liquids. In addition, the accelerator solution may be an aqueous solution of an acid selected from the group consisting of sulphuric acid, hydrochloric acid, citric acid, or tetrafluoroboric acid.

FIG. 4B illustrates forming a metal seeding layer 116 on the plating catalyst layer 112. In some embodiment, the metal seeding layer 116 is a copper seeding layer. In some embodiments, the metal seeding layer 116 may include aluminum, silver, nickel, or an alloy thereof.

The process of FIG. 4B includes an electroless plating method. During the electroless plating method, a thin copper layer is deposited as the metal seeding layer 116. In some embodiments, a thickness of the thin copper layer may be about 1-5 μm. In this condition, the plating catalyst layer 112 functions as a catalyst for the electroless plating of copper. In embodiments where the plating catalyst layer 112 is formed of a palladium colloid, the tin remained in the plating catalyst layer 112 enhances adhesion of the copper seeding layer to the substrate 100.

During the electroless plating, the plating catalyst layer 112 provides negative charges (electrons) to the copper ions (e.g., Cu⁺⁺) presented in electrolyte environment. Thus, the thin copper layer is formed as the metal seeding layer 116, while the plating catalyst layer 112 improves binding of the metal seeding layer 116 to the substrate 100. In some embodiments, the plating catalyst layer 112 is formed as a non-continuous layer and is present on the surfaces of the opening 102 as clusters. In this condition, the thickness of the metal seeding layer 116 may be controlled by the cluster sizes of the plating catalyst layer 112. In some embodiments, a thickness of the metal seeding layer 116 is about 2-4 μm.

FIG. 4C illustrates forming a metal layer 120 to fill the area of the opening 102, thereby forming the conductive trace in the opening 102. In various embodiment, the metal layer 120 is a copper layer. In some examples, the metal layer 120 may include aluminum, silver, nickel, or an alloy thereof.

The metal layer 120 is formed on the metal seeding layer 116. In some embodiments, the process of FIG. 4C includes an electrochemical deposition (ECD) method. In this condition, the metal seeding layer 116 provides a sufficient cathode surface for reaction of copper ions in electrolysis of a solution containing a copper salt, for example copper sulphate. The binding energy of the metal layer 120 onto the substrate 100 is enhanced by the metal seeding layer 116 as well as the plating catalyst layer 112.

After the electrochemical deposition, the metal layer 120 may be planarized, for example, by a chemical-mechanical polishing (CMP) process to remove the excess copper from the top surface of the substrate 100. A conductive trace 130 is thus formed in the opening 102 of the substrate 100. The conductive trace 130 includes stacked layers of the metal layer 120, the metal seeding layer 116, and the plating catalyst layer 112. In addition, a molding compound may be applied to cover the conductive trace 130 after the planarizing process to protect the conductive trace 130 from oxidation and other damages. In various embodiments, a final product with the conductive trace 130 and the substrate 100 form a circuit, in which the conductive trace 130 forms interconnections between the different components of the circuit. The circuit may be a printed circuit board (PCB) or part of an integrated circuit (IC) or packaged integrated circuit. In some embodiments, the conductive trace 130 is used to replace wire bonding in a semiconductor chip.

In some embodiments the circuit in FIG. 4C is a single sided PCB that includes one metal layer, as the conductive trace 130 is on the top of the substrate 100. FIG. 4D is an example of the application of such a single sided PCB. In this embodiment, a device 140 is coupled to the conductive trace 130. In various embodiments, the device 140 is a surface mount device (SMD). In some embodiments, the device 140 can be mounted on the surface of the conductive trace 130 using surface mount technology (SMT). In some embodiments, the conductive trace 130 may form interconnections between devices in a circuit, where the devices include either SMD or through-hole devices.

FIGS. 5A-5F are illustrating forming conductive traces in a substrate 400, with cross-sectional views of forming a conductive trace. Some of the steps shown in FIGS. 5A-5F are similar to the steps described in FIGS. 1A-4C, so the details and variations concerning the similar steps will not be repeated. The substrate 400 corresponds to the substrate 100 described in FIGS. 1A-4C. In this embodiment, the substrate 400 may be used to form conductive traces in a double-sided PCB (two metal layers on both sides of one substrate or dielectric layer), or a multi-layer PCB (outer and inner layers of metal, alternating with layers of substrate or dielectric). In this condition, different metal layers of the PCB are coupled together with vias.

During process in FIG. 5B, an opening 404 is formed in the substrate 400. In this embodiment, the opening 404 includes a trench opening 405 and via openings 406 and 408 beneath the trench opening 405. The via openings 406 and 408 are formed to provide electrical connection between the conductive traces in different layers and metal lead frames. For instance, the via opening 406 is formed to provide interconnection between a conductive trace at the front side of the substrate 400 and a metal layer at the backside of the substrate 400, while the via opening 408 is formed to provide interconnection between a conductive trace at front side of the substrate 400 and an intermediate metal layer. In some embodiments, the process of FIG. 5B is performed by a laser patterning method. Parameters of a beam of the laser controls the dimension of the trench opening 405 as well as the dimensions of the via openings 406 and 408. For instance, a pulse duration, pulse energy, and beam spot size of the laser is tuned based on the desired dimension of the trench opening 405 and the vias 406 and 408. In some alternative examples, different etching technique such as photolithography and wet etching may be used instead of the laser patterning. The etching process may include a dry etch, a wet etch, or a combination of dry etch and wet etch. The dry etching process may implement fluorine-containing gas (e.g., CF₄, SF₆, CH₂F₂, CHF₃, and/or C₄F₈), chlorine-containing gas (e.g., Cl₂, CHCl₃, CCl₄, and/or BCl₃), bromine-containing gas (e.g., HBr and/or CHBr₃), oxygen-containing gas, iodine-containing gas, other suitable gases and/or plasmas, or combinations thereof. The number and dimension of the vias may be different based on the application.

After patterning the substrate 400 and forming the opening 404, during process in FIG. 5C, which corresponds to the process of FIG. 1C, a metal precursor layer 412 is formed on a surface and walls of the trench opening 405 and vias 406, 408. In some embodiments, the metal precursor layer 412 is formed conformally, with a substantially same thickness on the surface and the walls of the opening 404 and vias 406, 408. In some embodiments, the metal precursor layer 412 includes a noble metal colloid material. The noble metal includes palladium, for example. Alternatively, the metal precursor layer 412 may include different material such as gold, aluminum, titanium, tungsten, copper, nickel, chromium, platinum, germanium, selenium, or the like, oxides thereof. In this embodiment, the noble metal colloid is palladium colloid which is an effective catalyzer for metallization processes. The palladium colloid includes palladium-tin (Pd—Sn) colloidal particles. The presence of tin (Sn) in the palladium colloid material increases adhesion of the metal precursor layer 412 in the trench opening 405 and via openings 406 and 408.

In the same condition of the process described in FIG. 1C, the metal precursor layer 412 includes palladium colloid solution and the process in FIG. 5C is based on a laser-induced forward transfer (LIFT) method. During the LIFT method, a metallic material is selectively transferred from a donor substrate into the trench opening 405 and via openings 406 and 408. A pattern of the laser exposure on the donor substrate during the LIFT process corresponds to the pattern of the opening 404 formed in the substrate 400. In some embodiments, a first LIFT process may transfer the metallic material into the trench opening 405, while a second LIFT process transfers the metallic material into the vias 406 and 408. Different LIFT processes may be performed by different patterns, in which a first pattern is aligned with the pattern of the trench opening 405 and the second pattern is aligned with the via openings 406 and 408. In addition, more LIFT processes may be performed, where each process corresponds to a subset of openings or vias, in which each subset having substantially same parameters (e.g., depth of the vias or dimensions of the openings).

The process of FIG. 5D illustrates forming a plating catalyst layer 416 from the metal colloid of the metal precursor layer 412. In various embodiments, the process in FIG. 5D corresponds to the process described in FIG. 4A, which includes acceleration of the metal colloid. In some embodiments, when the metal precursor layer 412 includes a palladium colloid, the process in FIG. 5D includes acceleration of the palladium colloid. During the acceleration process of the palladium colloid, the tin shell is removed from the palladium nucleus. In this condition, an active catalyst layer of palladium remains in the trench opening 405 and via openings 406 and 408 to form the plating catalyst layer 416. Although the tin shell is removed from the palladium colloid during the acceleration process, still portions of tin material remain in the plating catalyst layer 416. The remaining tin material provides better adhesion of the metallic layer into the opening 404 and via openings 406 and 408 during the metallization process.

After forming the plating catalyst layer 416, during the process in FIG. 5E, a metal seeding layer 420 is formed on the plating catalyst layer 416. In some embodiments, the metal seeding layer 420 is a copper seeding layer. In some embodiments, the metal seeding layer 420 may include aluminum, silver, nickel, or an alloy thereof.

The process in FIG. 5E, which corresponds to the process described in FIG. 4B, includes electroless plating method. During the electroless plating method, a thin copper layer is deposited as the metal seeding layer 420. In some embodiments, a thickness of the thin copper layer may be about 1-5 μm. In this condition, the plating catalyst layer 416 functions as a catalyst for the electroless plating of copper. In embodiments where the plating catalyst layer 416 is formed of a palladium colloid, the tin remained in the plating catalyst layer enhances adhesion of the copper seeding layer to the substrate 400.

During the process in FIG. 5F, a metal layer 424 is formed on the metal seeding layer 420. In some embodiments, the process in FIG. 5F includes an electrochemical deposition (ECD) method. In this condition, the metal seeding layer 420 provides a sufficient cathode surface for reaction of copper ions in electrolysis of a solution containing a copper salt, for example copper sulphate. The binding energy of the metal layer 424 onto the substrate 400 is enhanced by the metal seeding layer 420 as well as the plating catalyst layer 416.

After the electrochemical deposition, the metal layer 424 may be planarized, for example, by a chemical-mechanical polishing (CMP) process to remove the excess copper from the top surface of the substrate 400. A conductive trace 430 is thus formed in the trench opening 405 and via openings 406 and 408 of the substrate 400. The conductive trace 430 includes stacked layers of the metal layer 424, the metal seeding layer 420, and the plating catalyst layer 416. In addition, a molding compound may be applied to cover the conductive trace 430 after the planarizing process to protect the conductive trace 430 from oxidation and other damages. In various embodiments, a final product with the conductive trace 430 and the substrate 400 form a circuit, in which the conductive trace 430 forms interconnections between the different components of the circuit. The circuit may in a package that includes a printed circuit board (PCB) or an integrated circuit (IC). In some embodiments, the conductive trace 430 is used to replace wire bonding in a semiconductor chip.

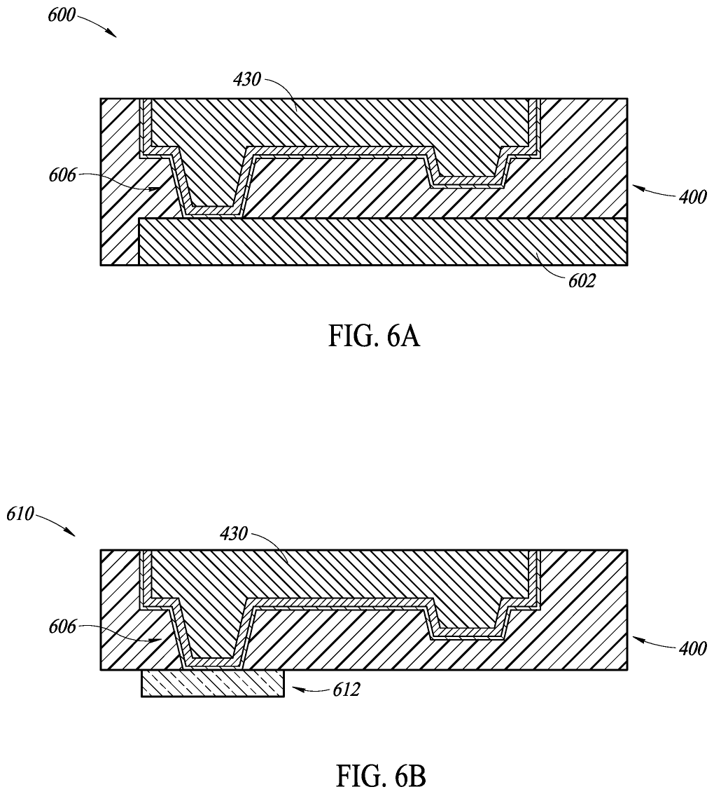

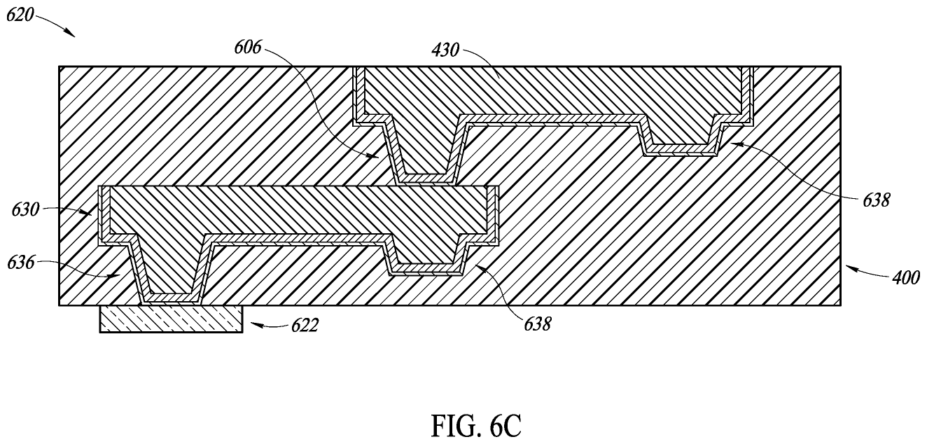

In some embodiments the circuit formed in process of FIGS. 5A-5F is a double sided PCB including two metal layers on both sides of one substrate 400 that includes two metal layers, as the conductive trace 430, in top of the substrate 400 that is coupled to a backside metal layer through one or more vias (e.g., via opening 406). FIGS. 6A-6C are examples of the application of such a double sided PCB. FIG. 6A is a circuit 600 including a metal layer 602 formed on the backside of the substrate 400. The metal layer 602 is coupled to the conductive trace 430 with the via 606. In this embodiment, the metal layer 602 may be a lead frame of the circuit 600. The conductive trace 430 may form interconnections between different components of the circuit 600. In some embodiments, the metal layer 602 may be coupled to different components or external circuits. The material of the metal layer 602 may be the same as the conductive trace 430 such as aluminum (Al), copper (Cu), tungsten (W), titanium (Ti), tantalum (Ta), or a combination thereof. In addition, the metal layer 602 may be formed by different deposition methods such as a chemical vapor deposition (CVD) process, a sub-atmospheric CVD (SACVD) process, a flowable CVD process, an atomic layer deposition (ALD) process, a physical vapor deposition (PVD) process, or other suitable process.

FIG. 6B is a circuit 610 including a device 612 coupled to the conductive trace 430 by the via 606. In various embodiments, the device 612 is a though-hole device which is coupled to the via 606. In this embodiment, the conductive trace 430 may form interconnections between devices in the circuit 610. In addition, the conductive trace 430 may form the lead frame which couples the components of the circuit 610 (e.g., the device 612) into an external circuit.

FIG. 6B is a multi-layer circuit 620 including the conductive trace 430 in a top layer of the substrate 400 and an intermediate conductive layer 630 which is coupled to the conductive trace 430 by the via 606. In some embodiments, different intermediate conductive layers may be coupled together with different vias, in which each via has a different depth, e.g., via 608). The intermediate conductive trace 630 includes vias 636 and 638. In this embodiment, a device 622 in coupled to the intermediate conductive trace 630 by the via 636. In some embodiments, the device 622 is a though-hole device. In addition, the conductive trace 430 may form the lead frame which couples the components of the circuit 620 (e.g., the device 622) into an external circuit. In various embodiments, more vias and devices may be added to the circuit 620 by the same process described in FIGS. 1A-5.

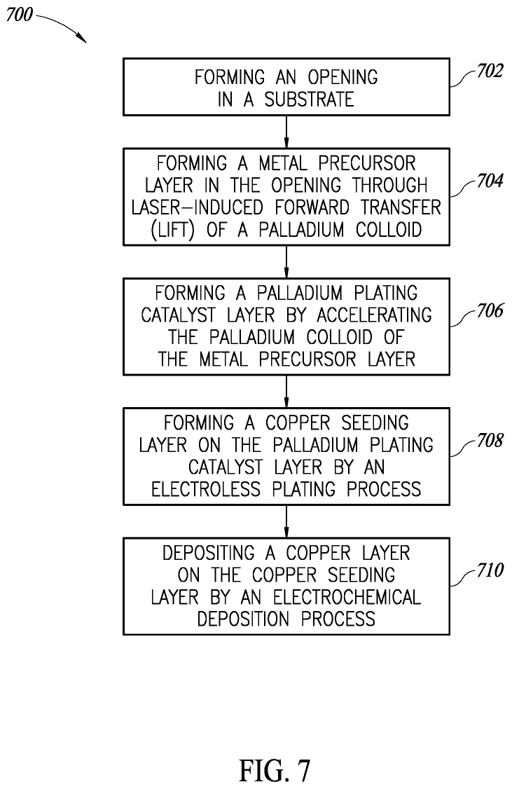

FIG. 7 is a flowchart 700 of the process described in embodiments of FIGS. 1A-5. At 702, an opening is formed in a substrate by a patterning method. The patterning method may be a laser-machining process in some embodiments. In some alternative embodiments, different etching techniques such as photolithography and etching process may be used instead of the laser-machining process. The etching process may include a dry etch, a wet etch, or a combination of dry etch and wet etch. The dry etching process may implement fluorine-containing gas (e.g., CF₄, SF₆, CH₂F₂, CHF₃, and/or C₄F₈), chlorine-containing gas (e.g., Cl₂, CHCl₃, CCl₄, and/or BCl₃), bromine-containing gas (e.g., HBr and/or CHBr₃), oxygen-containing gas, iodine-containing gas, other suitable gases and/or plasmas, or combinations thereof.

At 704, a metal precursor layer is formed on a bottom and sidewalls of the opening that is formed at 702. In various embodiments, the metal precursor layer is formed conformally. The process of 704 is based on a laser-induced forward transfer (LIFT) method. During the LIFT method, a metallic material is selectively transferred from a donor substrate into the opening. A pattern of the laser exposure on the donor substrate during the LIFT process corresponds to the pattern of the opening formed in the substrate. Thus, the metal precursor layer is only transferred on the patterned opening areas including the opening.

In some embodiments, the metal precursor layer includes a noble metal colloid material. The noble metal includes palladium. Alternatively, the metal precursor layer may include different noble metals such as gold and platinum. In addition, the metal precursor layer may include materials such as aluminum, titanium, tungsten, copper, nickel, chromium, germanium, selenium, or the like, oxides thereof, nitrides thereof, an alloy thereof, or any other combination thereof.

In this embodiment, the noble metal colloid is palladium colloid which is an effective catalyzer for metallization processes. The palladium colloid includes palladium-tin (Pd—Sn) colloidal particles. The presence of tin (Sn) in the palladium colloid material increases adhesion of the metal precursor layer in the opening of the substrate. In various embodiments, the palladium colloid material is formed on the donor substrate during the LIFT process at 704. The formation of the palladium colloid on the donor substrate may include a uniform deposition of palladium colloid solution. The palladium colloid solution has very high stability and high dissolvability in standard organic solvents that benefit strong catalytic activities.

At 706, a plating catalyst layer is formed from the metal colloid of the metal precursor layer formed by the LIFT process at 704. In various embodiments, the process of 706 includes acceleration of the metal colloid. During the acceleration process of the palladium colloid, the tin shell is removed from the palladium nucleus. In this condition, an active catalyst layer of palladium remains in the opening to form the plating catalyst layer. Although the tin shell is removed from the palladium colloid during the acceleration process, still portions of tin material remains in the plating catalyst layer. The remained tin material provides better adhesion of the metallic layer into the opening during the metallization process. In some embodiments, the metal precursor layer may have a thickness about 100 micrometers (μm), while the plating catalyst layer has a thickness about 5 angstroms (Å) after the acceleration process. In some embodiments, removing the tin shell may be based on dissolving of the tin shell into an accelerator solution. The accelerator solution may include a hydrochloride acid or different aqueous chloride, organic acid, mixed acid, and polar organic liquids. In addition, the accelerator solution may be an aqueous solution of an acid selected from the group consisting of sulphuric acid, hydrochloric acid, citric acid, or tetrafluoroboric acid.

At 708, a metal seeding layer is formed on the plating catalyst layer. In various embodiment, the metal seeding layer is a copper seeding layer. In some examples, the metal seeding layer may include aluminum, silver, nickel, or an alloy thereof.

The process 708 includes an electroless plating method. During the electroless plating method, a thin copper layer is deposited as the metal seeding layer. In some embodiments, a thickness of the thin copper layer may be about 1-5 μm. In this condition, the plating catalyst layer functions as a catalyst for the electroless plating of copper. In embodiments where the plating catalyst layer is formed of a palladium colloid, the tin remained in the plating catalyst layer enhances adhesion of the copper seeding layer to the substrate.

During the electroless plating, the palladium plating catalyst layer provides negative charges (electrons) to the copper ions (e.g., Cu⁺⁺) presented in electrolyte environment. Thus, the thin copper layer is formed as the copper seeding layer, while the palladium plating catalyst layer improves binding of the copper seeding layer into the substrate. The palladium plating catalyst layer creates a clustering area on the non-conductive material of the substrate, in which triggers reaction of the copper ions in the electrolyte environment for deposition the thin copper layer. In this condition, a thickness of the copper seeding layer may be controlled by the clustering areas of the palladium plating catalyst layer. In some embodiments, a thickness of the copper seeding layer is about 2-4 μm.

At 710, a metal layer is formed on the metal seeding layer. In some embodiments, the process 710 includes an electrochemical deposition (ECD) method. In this condition, the metal seeding layer provides a sufficient cathode surface for reaction of copper ions in electrolysis of a solution containing a copper salt, for example copper sulphate. The binding energy of the metal layer onto the substrate is enhanced by the metal seeding layer as well as the plating catalyst layer.

After the electrochemical deposition, the metal layer may be planarized, for example, by a chemical-mechanical polishing (CMP) process to remove the excess copper from the top surface of the substrate. A conductive trace is thus formed in the opening of the substrate. The conductive trace includes stacked layers of the metal layer, the metal seeding layer, and the plating catalyst layer. In addition, a molding compound may cover the conductive trace after the planarizing process to protect the conductive trace from oxidation and other damages. In various embodiments, a final product with the conductive trace and the substrate forms a circuit, in which the conductive trace forms interconnections between the different components of the circuit. The circuit may be a printed circuit board (PCB) or part of an integrated circuit (IC). In some embodiments, the conductive trace is used to replace wire bonding in a semiconductor chip.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method of forming a conductive trace, comprising:
forming an opening in a substrate;
forming a palladium precursor layer in the opening through laser-induced forward transfer of a palladium colloid from a donor substrate;
forming a palladium plating catalyst layer from the palladium precursor layer;
forming a copper seeding layer on the palladium plating catalyst layer by an electroless plating process; and
depositing a copper layer on the copper seeding layer to fill the opening.

2. The method of claim 1 wherein forming the opening comprises patterning the substrate using a laser patterning process.

3. The method of claim 1 wherein forming the palladium plating catalyst layer comprises accelerating the palladium colloid in the palladium precursor layer.

4. The method of claim 1 wherein the laser-induced forward transfer includes illuminating the donor substrate bay beam of a laser, the illuminating is based on a predetermined pattern corresponding to a pattern of the opening in the substrate.

5. The method of claim 1 wherein depositing the copper layer on the copper seeding layer is performed using an electrochemical deposition process.

6. The method of claim 1 wherein forming the opening includes forming a trench opening and one or more vias beneath the trench opening.

7. The method of claim 1 wherein the substrate includes a plastic material.

8. The method of claim 1 wherein the palladium plating catalyst layer includes tin (Sn).

9. The method of claim 8, further comprising:
forming the palladium colloid by reaction between palladium-chloride and tin-chloride.

10. A system, comprising:
a laser;
a controller coupled to the laser, the controller configured to:
form an opening in a substrate by exposing a first beam of the laser into the substrate; and
selectively transfer a metal colloid from a donor substrate into the opening in the substrate to form a metal precursor layer, by exposing a second beam of the laser into the donor substrate;
an accelerating subsystem configured to form a plating catalyst layer from the metal precursor layer;
an electroless plating subsystem configured to form a metal seeding layer on the plating catalyst layer; and
an electrochemical deposition subsystem configures to deposit a metal layer on the metal seeding layer.

11. The system of claim 10 wherein the metal colloid is a palladium colloid and the metal seeding layer is a copper seeding layer.

12. The system of claim 11 wherein the palladium colloid includes palladium-tin colloidal particles.

13. The system of claim 10 wherein the controller is further configured to form one or more via openings in the substrate by exposing a third beam of the laser into the substrate, wherein a wavelength and a power of the third beam are different than a wavelength and a power of the second beam.

14. The system of claim 10 wherein a wavelength and a power of the first beam is different than a wavelength and a power of the second beam.

15. A method, comprising:
forming a palladium colloid on a donor substrate;
forming an opening in a substrate;
selectively transferring the palladium colloid from the donor substrate into the opening in the substrate;
accelerating the palladium colloid to form a palladium plating catalyst layer;
forming a copper seeding layer on the palladium plating catalyst layer by an electroless plating process; and
depositing a copper layer on the copper seeding layer.

16. The method of claim 15 wherein the selectively transferring includes laser-induced forward transferring.

17. The method of claim 16 wherein the laser-induced forward transferring includes illuminating the donor substrate bay beam of a laser, the illuminating is based on a predetermined pattern corresponding to a pattern of the opening in the substrate.

18. The method of claim 17 wherein the illuminating includes tilting the beam of the laser on the donor substrate, the tilting causes transferring the palladium colloid into sidewalls of the opening in the substrate.

19. The method of claim 17 wherein the illuminating includes tilting the substrate, the tilting causes transferring the palladium colloid into sidewalls of the opening in the substrate.

20. The method of claim 15 wherein forming the opening in the substrate includes a laser-machining technique.
